(19) United States
(12) Patent Application Publication
(10) Pub. No.: US 2016/0056283 A1
(43) Pub. Date: Feb. 25, 2016

(54) SEMICONDUCTOR DEVICE AND METHOD FOR MANUFACTURING THE SAME

(71) Applicant: Kabushiki Kaisha Toshiba, Tokyo (JP)

(72) Inventor: Takuma Suzuki, Himeji Hyogo (JP)

(21) Appl. No.: 14/465,633

(22) Filed: Aug. 21, 2014

(51) Int. Cl. H01L 29/78; H01L 29/66; H01L 29/423; H01L 29/36; H01L 21/31; H01L 21/3105; H01L 21/04; H01L 29/16; H01L 21/324

(52) U.S. Cl. CPC H01L 29/7827; H01L 29/1608; H01L 29/66068; H01L 29/42364; H01L 21/324; H01L 21/31; H01L 21/3105; H01L 29/66666; H01L 21/049; H01L 29/36; H01L 29/4236

(57) ABSTRACT

According to one embodiment, semiconductor device including: a first semiconductor region; a second semiconductor region provided on the first semiconductor region; a third semiconductor region provided on the second semiconductor region, and the third semiconductor region having a higher impurity concentration than an impurity concentration of the first semiconductor region; a gate insulating film being in contact with the third semiconductor region, the second semiconductor region, and the first semiconductor region, and the gate insulating film having a region in which a nitrogen concentration becomes a lower concentration further away from a juncture portion of the third semiconductor region, the second semiconductor region, and the first semiconductor region, or being contact with the third semiconductor region, the second semiconductor region, and the first semiconductor region via a nitrogen-including layer; and a gate electrode provided on the gate insulating film.

### CROSS-REFERENCE TO RELATED APPLICATIONS

This application is based upon and claims the benefit of priority from Japanese Patent Application No. 2014-052794, filed on Mar. 14, 2014; the entire contents of which are incorporated herein by reference.

### FIELD

Embodiments described herein relate generally to a semiconductor device and a method for manufacturing the same.

### BACKGROUND

The conversion of Si to SiC has been considered for materials in a power MOSFET. The reason for this is that when comparing SiC with Si, the forbidden bandwidth is larger and the breakdown field, the saturated drift velocity, and the thermal conductivity are higher. The one problem in the use of SiC in a MOSFET is that channel resistance is great. For example, while a 4H-SiC crystal in which the Si-face becomes the outermost face is used as the semiconductor substrate, an interface state exists between the SiC substrate and a gate insulating film, and it is thought that interface state reduces the channel mobility (μ) of a MOSFET in which SiC is used. An increase in channel mobility is desired for a MOSFET in which SiC is used.

For example, there is a method for increasing channel mobility by reducing a density of interface state by terminating interface state with nitrogen (N), including nitrogen in a gate insulating film. On the other hand, electric charges injected into the gate insulating film are trapped when an electric potential is applied to the gate insulating film if nitrogen remains excessively in the gate insulating film which is away from the interface state terminated with nitrogen. Thereby, a gate threshold voltage does not become stable when a same electric potential is applied to the gate insulating film.

### BRIEF DESCRIPTION OF THE DRAWINGS

FIG. 1A is a schematic cross-sectional view illustrating a semiconductor device according to a first embodiment, and FIG. 1B illustrates a nitrogen concentration profile in a gate insulating film in the semiconductor device according to the first embodiment;

FIGS. 2A to 2C are schematic cross-sectional views illustrating a method for manufacturing the semiconductor device according to the first embodiment;

FIG. 3 schematically illustrates the nitrogen-terminated end of the base region according to the first embodiment;

FIG. 4 illustrates an example of a relationship between interface state energy and interface state density;

FIG. 5A is a schematic view of an example of a band structure of the base region, the gate insulating film, and the gate electrode, and FIG. 5B illustrates the relationship between time periods for applying a gate stress voltage and fluctuation of a threshold potential of the gate electrode;

FIG. 6 illustrates an example of an appearance of fluctuation of the threshold potential;

FIG. 7 is a schematic cross-sectional view illustrating a semiconductor device according to a second embodiment;

FIGS. 8A to 8C are schematic cross-sectional views illustrating a method for manufacturing the semiconductor device according to the second embodiment; and

FIGS. 9A to 9C are schematic cross-sectional views illustrating a method for manufacturing a semiconductor device according to the third embodiment.

### DETAILED DESCRIPTION

According to one embodiment, semiconductor device including: a first semiconductor region of a first conductivity type; a second semiconductor region of a second conductivity type provided on the first semiconductor region; a third semiconductor region of a first conductivity type provided on the second semiconductor region, and the third semiconductor region having a higher impurity concentration than an impurity concentration of the first semiconductor region; a gate insulating film being in contact with the third semiconductor region, the second semiconductor region, and the first semiconductor region, and the gate insulating film having a region in which a nitrogen concentration becomes a lower concentration further away from a juncture portion of the third semiconductor region, the second semiconductor region, and the first semiconductor region, or being contact with the third semiconductor region, the second semiconductor region, and the first semiconductor region via a nitrogen-including layer; and a gate electrode provided on the gate insulating film.

Hereinafter, embodiments will be described below with reference to the drawings. In the following description, the same reference numeral is applied to the same member, and for members that have been described once, the description is omitted as appropriate.

### First Embodiment

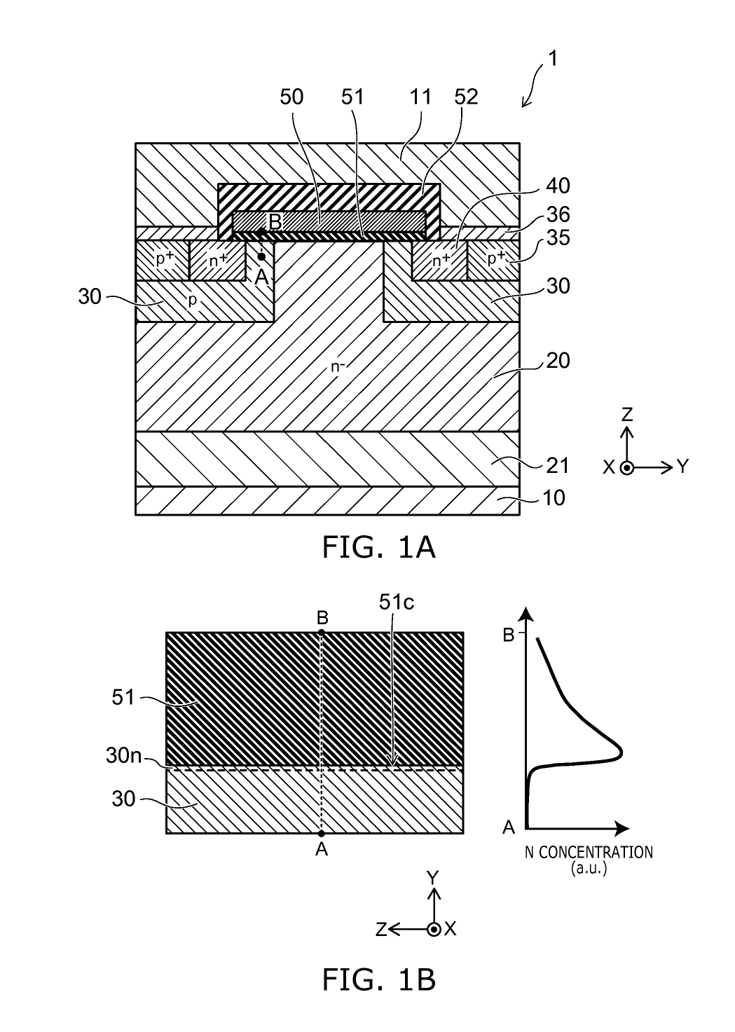

FIG. 1A is a schematic cross-sectional view illustrating a semiconductor device according to a first embodiment, and FIG. 1B illustrates a nitrogen concentration profile in a gate insulating film in the semiconductor device according to the first embodiment.

The impurity concentration in FIG. 1B is represented by the nitrogen concentration profile along line A-B in FIG. 1A. The impurity concentration in FIG. 1B is represented with arbitrary units (a.u.) along the horizontal axis.

A semiconductor device 1 illustrated in FIG. 1A is a metal oxide semiconductor field effect transistor (MOSFET) with a vertical electrode structure having silicon carbide (SiC). An n-channel MOSFET is illustrated here as an example.

The semiconductor device 1 comprises a drain electrode 10 and a source electrode 11 aligned in the Z direction. An n-type drift region 20 (first semiconductor region) is provided between the drain electrode 10 and the source electrode 11. An n⁺-type drain region 21 is provided between the drain electrode 10 and the drift region 20.

A p-type base region 30 (second semiconductor region) is provided on the drift region 20. An n⁺-type source region 40 (third semiconductor region) is provided on the base region 30. The impurity concentration of the source region 40 is higher than the impurity concentration of the drift region 20. A p⁺-type contact region 35 is provided between the base region 30 and the source electrode 11. The contact region 35 is positioned beside the source region 40. The impurity concentration of the contact region 35 is higher than the impurity concentration of the base region 30. A silicide film 36 is provided between the source electrode 11 and the source region 40 and the contact region 35.

As illustrated in FIG. 1B, a gate electrode 50 is in contact with the source region 40, the base region 30, and the drift region 20 via a gate insulating film 51. The gate insulating film 51 includes nitrogen (N). The top portion and the side portions of the gate electrode 50 are covered by an interlayer insulating film 52 so as to be insulated from the source electrode 11.

The gate insulating film 51 includes a region in which the nitrogen concentration decreases further away from a juncture portion 51c that joins the gate insulating film 51 to the source region 40, the base region 30, and the drift region 20. Moreover, a region 30n in which the nitrogen is terminated is present on the surface of the base region 30 facing the gate insulating film 51.

Herein, n⁺-type and n-type may be referred to as a first conductivity type, and p⁺-type and p-type may be referred to as a second conductivity type in the embodiments. The order of n⁺-type and n-type and the order of p⁺-type and p-type indicate a decrease in the impurity concentration.

The abovementioned “impurity concentration” refers to an effective concentration of impure elements that contribute to conductivity of the semiconductor material. For example, if the semiconductor material includes an impurity element that is a donor and an impurity element that is an acceptor, the concentration excluding the portion canceled out by the donor and the acceptor among the activated impurity elements is considered the impurity concentration.

The main ingredient of the drift region 20, the drain region 21, the base region 30, the source region 40, and the contact region 35 includes silicon carbide (SiC).

Phosphorus (P) or nitrogen (N) and the like, for example, are used as the impurity element in the first conductivity type. Aluminum (Al) or boron (B), for example, are used as the impurity element in the second conductivity type.

The gate electrode 50 includes a polysilicon or a metal introduced by the impurity element. The insulating film in the embodiment includes, for example, a silicon oxide (SiOₓ) or a silicon nitride (SiNₓ) and the like.

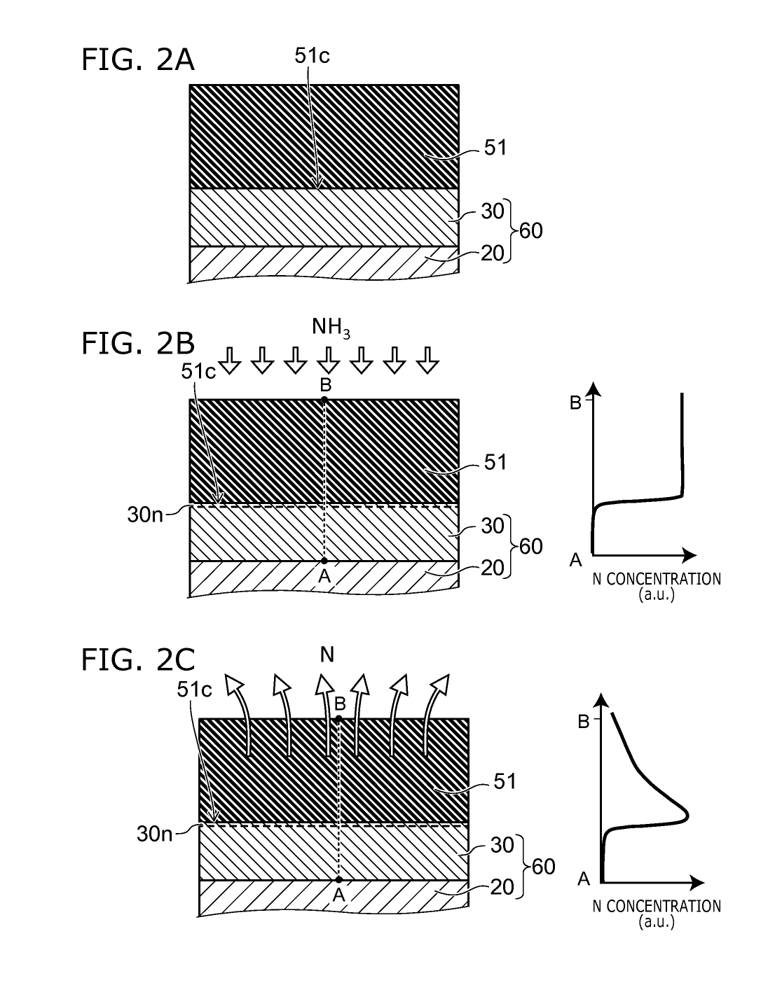

FIGS. 2A to 2C are schematic cross-sectional views illustrating a method for manufacturing the semiconductor device according to the first embodiment.

As illustrated in FIG. 2A, first a stacked body 60 is prepared that has the drift region 20 that includes silicon carbide and the base region 30 that includes silicon carbide. The base region 30 is provided on the drift region 20. Next, the gate insulating film 51 is formed with, for example, chemical vapor deposition (CVD) so as to be in contact with the base region 30 in the stacked body 60. The thickness of the gate insulating film 51 is, for example, 20 nm to 100 nm, or for example, 60 nm. When forming the gate insulating film 51, the stacked body 60 may be heated at 700° C. to 900° C., or for example, 800° C.

Next, as illustrated in FIG. 2B, the base region 30 and the gate insulating film 51 are heated in an atmosphere of nitrogen-including gas (for example, ammonia (NH₃), or nitrogen (N₂) and the like). The nitrogen-including gas here is defined as a gas that includes nitrogen but does not include oxygen. The heating is conducted at a temperature of 900° C. to 1500° C., or for example, 1100° C. to 1300° C. The time period for conducting the heating is, for example, 30 minutes to 3 hours, or for example, 1 hour. As a result, the nitrogen-including gas is diffused from the surface of the gate insulating film 51 into the base region 30 and the surface of the base region 30 facing the gate insulating film 51 is terminated with nitrogen (N).

Nitrogen (N) remains in the gate insulating film 51. For example, an example of a nitrogen concentration profile along line A-B is illustrated in the figure on the right in FIG. 2B. The nitrogen concentration in the gate insulating film 51 is approximately uniform from A to B.

Next, as illustrated in FIG. 2C, the base region 30 and the gate insulating film 51 are heated in an atmosphere of a nitrogen- and oxygen-including gas. The nitrogen- and oxygen-including gas is, for example, a nitrous oxide (N₂O), a nitric monoxide (NO), nitrogen (N₂), or oxygen (O₂). Various types may be mixed among these nitrogen-including gases and the partial pressure of the nitrogen-oxygen in the nitrogen- and oxygen-including gas may be adjusted. Moreover, the partial pressure of the nitrogen-oxygen may be adjusted by mixing in a noble gas such as Ar. The heating is conducted at a temperature, for example, 900° C. to 1500° C., or for example, 1200° C. The time period for conducting the heating is, for example, 30 minutes to 5 hours. As a result, the nitrogen in the gate insulating film 51 is released from the surface of the gate insulating film 51. As a result, the nitrogen concentration profile in the gate insulating film 51 assumes the state illustrated in the figure on the right in FIG. 2C.

That is, after the stacked body 60 and the gate insulating film 51 are heated in the nitrogen- and oxygen-including gas atmosphere in the first embodiment, the surface of the base region 30 facing the gate insulating film 51 is effectively terminated with nitrogen. Moreover, the nitrogen concentration in the gate insulating film 51 is controlled so as to allow a region to be present in which the nitrogen concentration in the gate insulating film 51 decreases further away from the juncture portion 51c of the stacked body 60 and the gate insulating film 51.

Next, a description will be provided of the effects of the first embodiment.

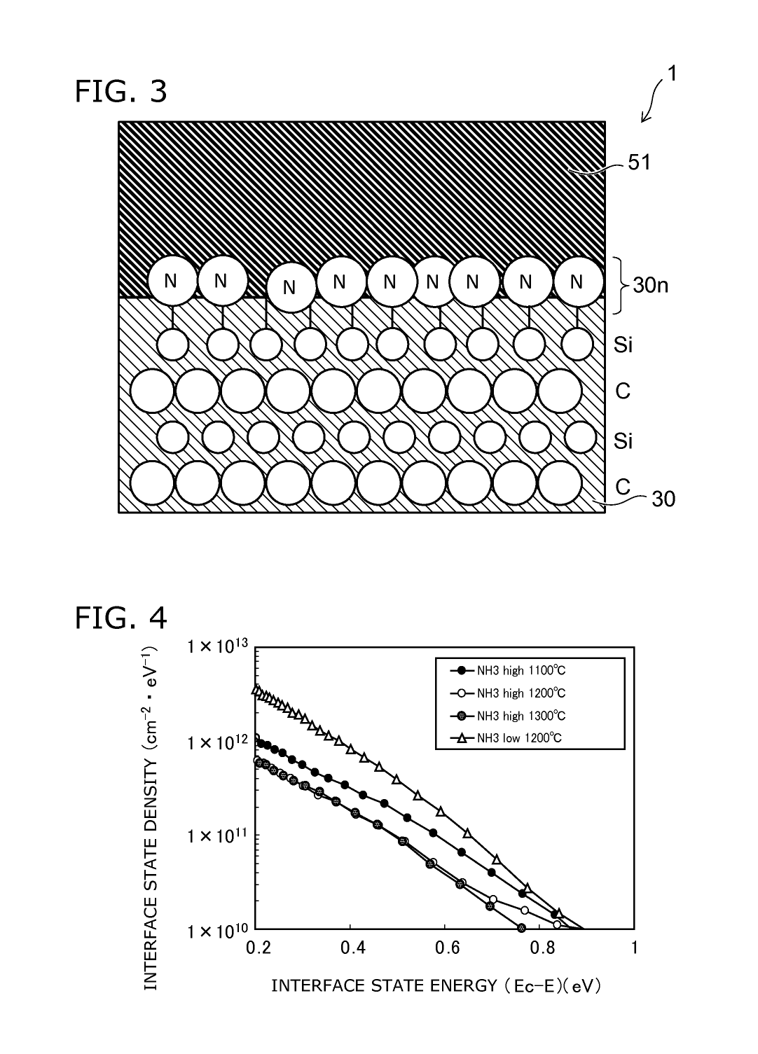

FIG. 3 schematically illustrates the nitrogen-terminated end of the base region according to the first embodiment.

For example, the base region 30 of the semiconductor device 1 includes 4H-SiC crystals and the Si face thereof becomes the outermost surface. The Si face that is the outermost surface is effectively terminated with nitrogen (N).

FIG. 4 illustrates an example of a relationship between interface state energy and interface state density.

FIG. 4 illustrates the relationship between interface state energy (eV) and interface state density (cm⁻² eV⁻¹) when the heating temperature is changed in a range of 1100° C. to 1300° C. and the ammonia atmosphere is divided into a high concentration level and a low concentration level. The heating time period is the same for all conditions.

It can be seen in FIG. 4 that interface state density decreases in correspondence with the ammonia atmosphere approaching a higher concentration as the heating temperature increases. For example, the interface state density is the lowest under the condition of a high-concentration ammonia atmosphere and a heating temperature of 1300° C. when the interface state energy near the conduction band end, whose effect on the channel mobility is high, is 0.2 (eV). This means that a fault (for example, a dangling bond) present in the gate insulating film 51 and the base region 30 (4H-SiC crystal) is effectively terminated with the nitrogen. Specifically, an SiC-MOSFET with a high channel mobility (μ) can be formed due to heating in only the ammonia atmosphere.

However, when nitrogen remains in the gate insulating film 51 as in the nitrogen concentration profile illustrated in FIG. 2B, a gate threshold potential (Vth) of the MOSFET may fluctuate when a negative bias is continuously applied to the gate electrode 50.

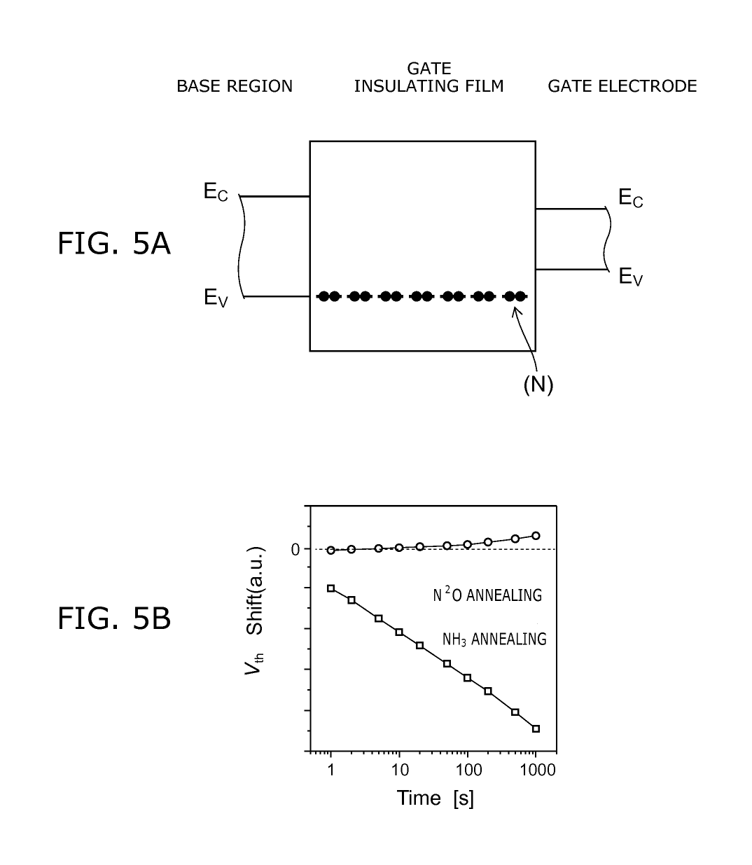

FIG. 5A is a schematic view of an example of a band structure of the base region, the gate insulating film, and the gate electrode, and FIG. 5B illustrates the relationship between time periods for applying a gate stress voltage and fluctuation of a threshold potential of the gate electrode.

For example, as illustrated in FIG. 5A, when nitrogen remains in the gate insulating film, an energy level (N) caused by nitrogen may be formed near the conduction band. Positive holes are easily trapped in the energy level caused by nitrogen and the gate insulating film takes on an electric charge due to the trapping of the positive holes. Specifically, the threshold potential (Vth) of the gate electrode easily fluctuates with the passage of the time period for applying the gate stress voltage as illustrated in FIG. 5B when heating with only an ammonia atmosphere.

Accordingly, FIG. 5B illustrates the appearance of the fluctuation of the threshold potential in only a nitrous oxide atmosphere. The horizontal axis in FIG. 5B represents the time period for applying the gate stress voltage, and the vertical axis represents a shift amount (arbitrary units) of the threshold potential. Less nitrogen remains in the gate insulating film when heating in only the nitrous oxide atmosphere than when heating in only the ammonia atmosphere. As a result, fluctuation of the threshold potential is less likely to occur. However, because nitrous oxide molecules include oxygen, the surface of the base region is not sufficiently terminated with nitrogen in comparison to ammonia, and the goal of sufficient channel mobility may not be achieved when heating with only the nitrous oxide atmosphere.

Accordingly, a nitrogen-including gas and a nitrogen- and oxygen-including gas are used and the respective heating conditions (temperature, time, atmosphere concentration, etc.) are suitably adjusted in the first embodiment. As a result, the surface of the base region 30 facing the gate insulating film 51 is terminated with nitrogen (N) and a structure in which the nitrogen concentration in the gate insulating film 51 is reduced can be formed. That is, a highly reliable semiconductor device is achieved.

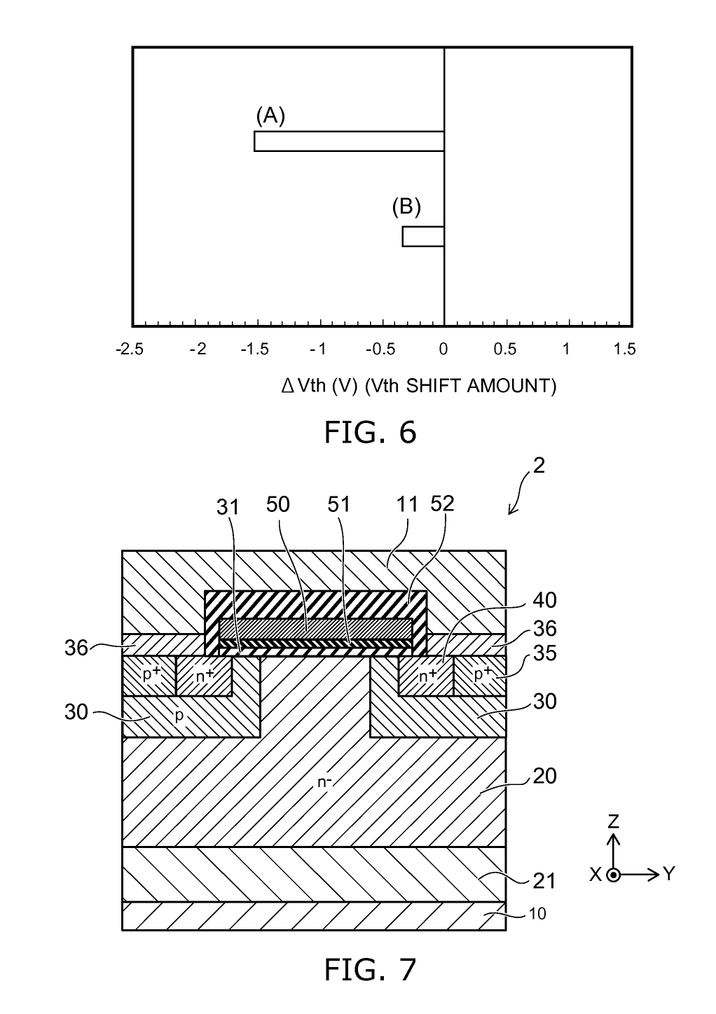

FIG. 6 illustrates an example of an appearance of fluctuation of the threshold potential.

The horizontal axis in FIG. 6 represents a shift amount (ΔVth) of the threshold potential (Vth) after the application of a gate stress voltage, and the bars in FIG. 6 signify the fluctuation of the threshold potential when, for example, −20 V is applied to the gate electrode. The (A) in FIG. 6 represents the result when a thermal treatment is conducted in only an atmosphere of a nitrogen-including gas (for example, NH₂/N₂). The (B) in FIG. 6 represents the result when, after conducting the thermal treatment in the atmosphere of the nitrogen-including gas (for example, NH₃/N₂), a thermal treatment is conducted in an atmosphere of a nitrogen- and oxygen-including gas (for example, N₂O/N₂).

Based on the results in FIG. 6, it can be seen that the fluctuation of the threshold potential in result (B), in which the thermal treatment is conducted in the atmosphere of the nitrogen- and oxygen-including gas is conducted after conducting the thermal treatment in the nitrogen-including gas, is about one-fifth of that of the fluctuation in result (A) in which the thermal treatment is conducted in only an atmosphere of the nitrogen-including gas.

In this way, while the channel mobility increases when using only the nitrogen-including gas, the threshold potential tends to fluctuate more easily when a negative bias is applied to the gate electrode. Moreover, while the channel mobility when only using the nitrogen- and oxygen-including gas is less than the channel mobility when using only the nitrogen-including gas, fluctuation of the threshold potential is less likely to occur. Accordingly, when using a nitrogen-including gas and a nitrogen- and oxygen-including gas as in the first embodiment, the channel mobility increases and fluctuation of the threshold potential is less likely to occur.

### Second Embodiment

FIG. 7 is a schematic cross-sectional view illustrating a semiconductor device according to a second embodiment.

A semiconductor device 2 has, in addition to the structure of the semiconductor device 1, a nitrogen-including layer 31 that is in contact with the source region 40, the base region 30, and the drift region 20. The gate electrode 50 is in contact with the source region 40, the base region 30, and the drift region 20 through the nitrogen-including layer 31 and the gate insulating film 51. The nitrogen-including layer 31 herein is an oxide layer that has been nitrided.

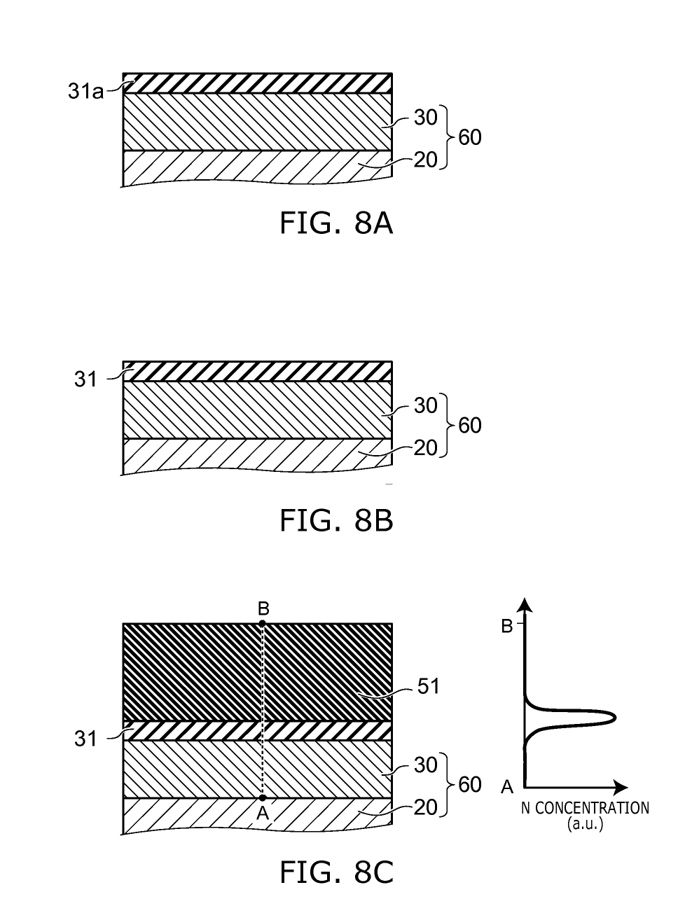

FIGS. 8A to 8C are schematic cross-sectional views illustrating a method for manufacturing the semiconductor device according to the second embodiment.

FIGS. 8A to 8C illustrate the nitridization of the oxide layer provided on the surface of the base region 30, while the source region 40 and the drift region 20 are omitted in the drawings.

As illustrated in FIG. 8A, the stacked body 60 having the drift region 20 and the base region 30 is prepared first. Next, an oxide layer 31a is formed by, for example, thermal oxidation CVD so as to be in contact with the base region 30. The thickness of the oxide layer 31a is, for example, 0.4 nm to 10 nm, or for example, 1 nm.

Next, as illustrated in FIG. 8B, the base region 30 and the oxide layer 31a are heated in an atmosphere of a nitrogen-including gas (for example, ammonia (NH₃), nitrous oxide (N₂O), nitric monoxide (NO), or nitrogen (N₂). The heating is conducted at a temperature of 900° C. to 1500° C., or for example, 1100° C. to 1300° C. The time period for conducting the heating is, for example, 30 minutes to 3 hours. As a result, the nitrogen-including gas is diffused inside the oxide layer 31a and the oxide layer 31a is nitrided and is changed to the nitrogen-including layer 31. Furthermore, the surface of the base region 30 facing the gate insulating film 51 is terminated with nitrogen (N).

Next, in FIG. 8C, the gate insulating film 51 is formed by CVD, for example, so as to be in contact with the nitrogen-including layer 31. The thickness of the gate insulating film 51 is, for example, 20 nm to 100 nm, or for example, 60 nm. A nitrogen concentration profile from the base region 30 to the gate insulating film 51 is developed as illustrated in the figure on the right in FIG. 8C in the second embodiment.

Because the oxide layer 31a in contact with the base region 30 is nitrided in the second embodiment, the surface of the base region 30 facing the gate insulating film 51 is effectively terminated with nitrogen. Moreover, because the gate insulating film 51 is formed after forming the nitrogen-including layer 31, the gate insulating film 51 does not include nitrogen and the fluctuation of the threshold potential of the gate electrode 50 is suppressed.

### Third Embodiment

The abovementioned nitrogen-including layer 31 is not limited to the second embodiment, and may be formed with the method illustrated below.

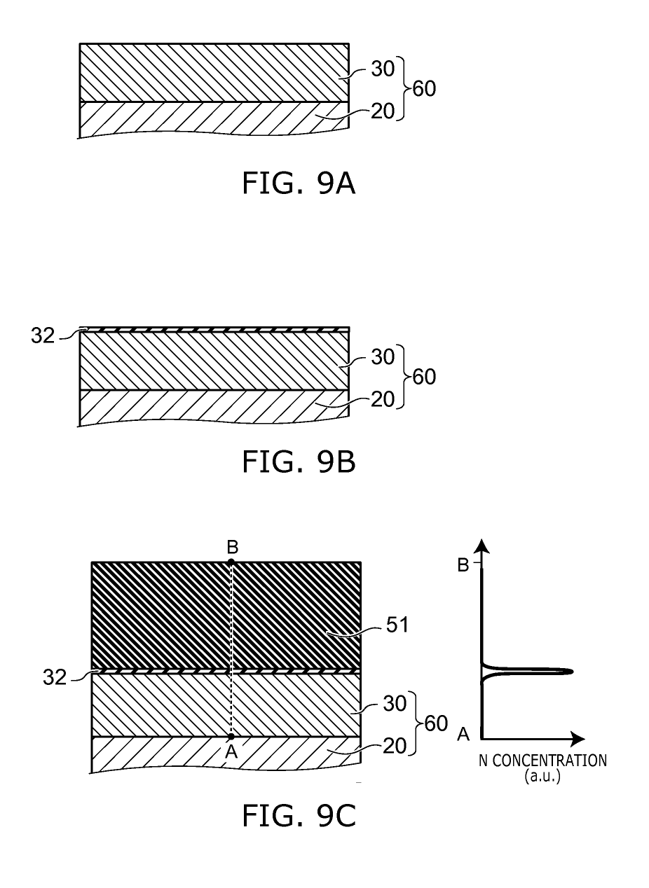

FIGS. 9A to 9C are schematic cross-sectional views illustrating a method for manufacturing a semiconductor device according to the third embodiment.

FIGS. 9A to 9C illustrate the nitridization of an oxide layer provided on the surface of the base region 30, while the source region 40 and the drift region 20 are omitted in the drawings.

As illustrated in FIG. 9A, first the stacked body 60 is prepared that has the drift region 20 and the base region 30.

Next, as illustrated in FIG. 9B, the surface of the base region 30 is exposed to a nitrogen-including gas (for example, ammonia (NH₃), nitrous oxide (N₂O), nitric monoxide (NO), or nitrogen (N₂)) and heated in an atmosphere of the nitrogen-including gas. The heating is conducted at a temperature of 900° C. to 1500° C., or for example, 1100° C. to 1300° C. The time period for conducting the heating is, for example, 30 minutes to 3 hours. As a result, the surface of the base region 30 facing the gate insulating film 51 is terminated with nitrogen (N).

Before nitriding the surface of the base region 30, acid cleaning may be conducted on the surface of the base region 30 and a natural oxidation film formed on the surface of the base region 30 may be removed.

Next, in FIG. 9C, the gate insulating film 51 is formed so as to be in contact with a nitrogen-including layer 32. In the third embodiment, a nitrogen concentration profile from the base region 30 to the gate insulating film 51 is developed as illustrated in the figure on the right in FIG. 9C. The thickness of the nitrogen-including layer 32 is less than that of the nitrogen-including layer 31.

Because of the direct nitridization of the surface layer of the base region 30 in the third embodiment, the surface of the base region 30 facing the gate insulating film 51 is effectively terminated with nitrogen. Moreover, because the gate insulating film 51 is formed after forming the nitrogen-including layer 32, the gate insulating film 51 does not include nitrogen and the fluctuation of the threshold potential of the gate electrode 50 is suppressed.

While a vertical MOSFET in a planar gate structure has been illustrated in the embodiments, the gate electrode 50 may have a trench gate structure so long as the same affects are achieved. Moreover, a p⁺-type collector region may be interposed between the drain electrode 10 and the drain region 21 as an insulated gate bipolar transistor (IGBT).

While a vertical MOSFET with a planar gate structure which uses 4H-SiC crystals in which the outermost surface is a Si face, that is a (0001) face according to Miller index notation, is illustrated in the embodiments, the crystal face to be the outermost face may be selected and used from any crystal face as the semiconductor substrate. For example, the same effects may be achieved with a MOSFET that uses crystals in which the 4H-SiC crystal face to be the outermost surface is a {0001}, {11-20}, {10-10}, or {03-38} crystal face or an off-cut face thereof.

The term “on” when expressed as “component A is provided on component B” in the above embodiments may be used to signify that component A is provided on component B and is in contact with component B, as well as component A is provided above component B without being in contact with component B. Moreover the phrase “component A is provided on component B” may be applied to a case in which component A and component B are inverted and component A is positioned below component B, or a case where component A and component B are disposed beside each other. This is because even if the semiconductor devices according to the embodiments are rotated, the structure of the semiconductor devices does not change before or after being rotated.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A semiconductor device, comprising:
a first semiconductor region of a first conductivity type;
a second semiconductor region of a second conductivity type provided on the first semiconductor region;
a third semiconductor region of a first conductivity type provided on the second semiconductor region, and the third semiconductor region having a higher impurity concentration than an impurity concentration of the first semiconductor region;
a gate electrode provided on the third semiconductor region, the second semiconductor region, and the first semiconductor region; and
a gate insulating film being in contact with the gate electrode, the third semiconductor region, the second semiconductor region, and the first semiconductor region, and the gate insulating film having a region in which a nitrogen concentration of the gate insulating film becomes a lower concentration further away from the second semiconductor region, and the nitrogen concentration on a side of the gate insulating film in proximity to the second semiconductor region is larger than the nitrogen concentration on a side of the gate insulating film in proximity to the gate electrode.

2. The device according to claim 1, wherein:
the gate electrode is provided on the gate insulating film.

3. The device according to claim 1, further comprising:
a first electrode electrically connected to the third semiconductor region; and
a second electrode electrically connected to the first semiconductor region,
the third semiconductor region, a portion of the second semiconductor region, and a portion of the first semiconductor region are arranged in a direction crossing a direction from the second electrode toward the first electrode.

4. The device according to claim 3, wherein:
the gate electrode is a planer type gate electrode.

5. The device according to claim 3, further comprising:
a first electrode electrically connected to the third semiconductor region; and
a silicide film provided between the first electrode and the third semiconductor region.

6. The device according to claim 1, wherein:
the second semiconductor region includes silicon carbide.

7. The device according to claim 1, wherein:
the second semiconductor region includes a 4H-SiC crystal.

8. The device according to claim 1, wherein:
a surface of the second semiconductor region is terminated with a layer including nitrogen.

9. A method for manufacturing a semiconductor, the method comprising:
preparing a first semiconductor region of a first conductivity type, and a second semiconductor region of a second conductivity type provided on the first semiconductor region;
forming a gate insulating film in contact with the second semiconductor region;
heating the second semiconductor region and the gate insulating film in a nitrogen-including gas atmosphere;
heating the second semiconductor region and the gate insulating film in a nitrogen- and oxygen-including gas atmosphere; and
controlling a nitrogen concentration in the gate insulating film such that the nitrogen concentration decreases further away from the second semiconductor region, and the nitrogen concentration on a side of the gate insulating film in proximity to the second semiconductor region being larger than the nitrogen concentration on a side of the gate insulating film in proximity to the gate electrode.

10. The method according to claim 9,
wherein:
the first semiconductor region that includes silicon carbide is used.

11. The method according to claim 9, wherein:
the second semiconductor region that includes silicon carbide is used.

12. The method according to claim 9, wherein:
the nitrogen-including includes ammonia or nitrogen.

13. The method according to claim 9, wherein:
the heating in the nitrogen-including gas is performed at a temperature of 900° C. to 1500° C.

14. The method according to claim 9, wherein:
the heating in a nitrogen-including gas is performed at a temperature of 1100° C. to 1300° C.

15. The method according to claim 9, wherein:
a time period for the heating in the nitrogen-including gas is 30 minutes to 3 hours.

16. The method according to claim 9, wherein:
the nitrogen- and oxygen-including gas includes one of nitrous oxide, nitric monoxide, nitrogen, and oxygen.

17. The method according to claim 9, wherein:
the heating in the nitrogen- and oxygen-including gas is performed at a temperature of 900° C. to 1500° C.

18. The method according to claim 9, wherein:
a time period for the heating in the nitrogen- and oxygen-including gas is 30 minutes to 5 hours.

19. The method according to claim 9, wherein:
a surface of the second semiconductor region is terminated with a layer including nitrogen.

20. The method according to claim 9, wherein:
a partial pressure of the nitrogen- and oxygen-including gas is adjusted by mixing the nitrogen- and oxygen-including gas with a noble gas.
